(19) United States
(12) Patent Application Publication
(10) Pub. No.: US 2024/0065085 A1
(43) Pub. Date: Feb. 22, 2024

(54) MASK AND METHOD FOR MANUFACTURING DISPLAY PANEL USING THE SAME

(71) Applicant: Samsung Display Co., Ltd., Yongin-si (KR)

(72) Inventors: SEUNGPYO HONG, Yongin-si (KR); HANUL KWEN, Yongin-si (KR)

(73) Assignee: Samsung Display Co., Ltd., Yongin-si (KR)

(21) Appl. No.: 18/318,828

(22) Filed: May 17, 2023

(30) Foreign Application Priority Data
Aug. 18, 2022 (KR) 10-2022-0103142

(51) Int. Cl. H10K 71/16; H10K 59/12; C23C 14/04; C23C 16/04

(52) U.S. Cl. CPC H10K 71/166; H10K 59/1201; H10K 71/164; C23C 14/042; C23C 16/042

(57) ABSTRACT

A mask including a base sheet and at least one protrusion. The base sheet includes a first surface on which a target substrate is seated, a second surface that faces the first surface, and an inside surface portion that defines an opening formed through the first surface and the second surface. The at least one protrusion extends from a selected inside surface of the inside surface toward the opening, in a first region of the base sheet. The at least one protrusion includes a stepped surface. A gap between the stepped surface and the target substrate is greater than a gap between the first surface and the target substrate. The at least one protrusion is not provided extending from a non-selected inside surface of the inside surface portion in a second region of the base sheet.

### CROSS-REFERENCE TO RELATED APPLICATION(S)

This application claims priority to and benefits of Korean Patent Application No. 10-2022-0103142 under 35 U.S.C. § 119, filed on Aug. 18, 2022 in the Korean Intellectual Property Office, the entire contents of which are incorporated herein by reference.

### BACKGROUND

### 1. Technical Field

Embodiments of the disclosure described herein relate to a mask having improved process yield and deposition accuracy and a method for manufacturing a display panel using the mask.

### 2. Description of the Related Art

A display panel includes multiple pixels. Each of the pixels includes a drive element such as a transistor and a display element such as an organic light emitting diode. The display element may be formed by stacking an electrode and organic layers and inorganic layers on a substrate.

The electrode and the organic layers and inorganic layers included in the display element may be a deposition pattern formed in a predetermined or selected region through a deposition process. The deposition pattern may be formed by using a mask having an opening defined in a predetermined or selected region thereof.

### SUMMARY

Embodiments of the disclosure provide a mask for improving deposition accuracy for a deposition process and a method for manufacturing a display panel using the same.

According to an embodiment, a mask may include a base sheet and at least one protrusion. The base sheet may include a first surface on which a target substrate is seated, a second surface that faces the first surface, and an inside surface portion that defines an opening formed through the first surface and the second surface. The at least one protrusion may extend from a selected inside surface of the inside surface portion toward the opening, in a first region of the base sheet. The at least one protrusion may include a stepped surface. A gap between the stepped surface and the target substrate may be greater than a gap between the first surface and the target substrate, and the at least one protrusion may not be provided extending from a non-selected inside surface of the inside surface portion in a second region of the base sheet.

The at least one protrusion may include first and second boundary surfaces that are adjacent to the second region and that extend from the inside surface.

The first and second boundary surfaces may include different shapes.

The at least one protrusion may include a plurality of protrusions, and a plurality of boundary surfaces corresponding to the plurality of protrusions may be provided.

The inside surface portion may include first to fourth corner portions, and at least one of the first and second boundary surfaces may be located on at least one of the first to fourth corner portions.

The first to fourth corner portions may include a curvature.

The at least one protrusion may protrude from at least one of the first to fourth corner portions.

At least one of the first to fourth corner portions may be included in the second region.

The inside surface portion may include a first inside surface, a second inside surface, a third inside surface and a fourth inside surface. The first and third inside surfaces may be parallel to a first direction, and the second and fourth inside surfaces may be parallel to a second direction intersecting the first direction.

The first inside surface may be spaced apart from the third inside surface in the second direction, and the at least one protrusion may protrude from the first inside surface or the third inside surface.

The at least one protrusion may be integrally formed without protruding and separating from the adjacent second or fourth inside surface.

The at least one protrusion may be integrally formed without protruding and separating from a portion of the adjacent second inside surface and a portion of the adjacent fourth inside surface.

The at least one protrusion may include a plurality of protrusions. The second inside surface may be spaced apart from the fourth inside surface in the first direction. The plurality of protrusions may protrude from the second inside surface and the fourth inside surface, respectively.

The plurality of protrusions may protrude from a portion of the second inside surface and a portion of the fourth inside surface corresponding to the portion of the second inside surface, respectively.

At least one of the first and second boundary surfaces may be adjacent to at least one of the first to fourth inside surfaces.

The inside surface portion may include a vertical surface physically connected to the first surface in the second region and perpendicular to the first surface, and an inclined surface that physically connects the vertical surface and the second surface and that is inclined in a direction away from the opening.

The opening may be provided in plural, each including a same planar shape.

According to an embodiment, a method for manufacturing a display panel may include forming a circuit layer disposed on a base layer, and forming an element layer that is disposed on the circuit layer and that includes a common layer. The forming of the element layer may include forming the common layer using a mask. The common layer may include a first end portion including a first sectional structure and a second end portion including a second sectional structure different from the first sectional structure. The mask may include a base sheet and at least one protrusion. The base sheet may include a first surface on which a target substrate is seated, a second surface that faces the first surface, and an inside surface portion that defines an opening formed through the first surface and the second surface. The at least one protrusion may extend from a selected inside surface of the inside surface portion toward the opening, in at least one first region of the base sheet corresponding to the first end portion of the common layer. The at least one protrusion may include a stepped surface including a step from the first surface. The at least one protrusion may not be provided in extending from a non-selected inside surface of the inside surface portion in a second region of the base sheet corresponding to the second end portion of the common layer.

The base layer may include a display region and a non-display region. The display panel may include a plurality of data lines that are arranged in the display region in a first direction and that extend in a second direction intersecting the first direction and a plurality of connecting patterns that electrically connect connecting lines connected to a data driver disposed in the non-display region and the plurality of data lines. Each of the plurality of connecting patterns may include a first line that is connected to one of the plurality of data lines and that extends in the first direction and a second line that is connected to the first line and that extends in the second direction.

Contact portions between the first lines and the data lines may be disposed in the display region.

### BRIEF DESCRIPTION OF THE DRAWINGS

The above and other objects and features of the disclosure will become apparent by describing in detail embodiments thereof with reference to the accompanying drawings.

FIG. 1 is a schematic perspective view illustrating a mask according to an embodiment of the disclosure.

FIG. 2A is a schematic sectional view of the mask taken along line I-I′ of FIG. 1.

FIG. 2B is a schematic sectional view of the mask according to an embodiment of the disclosure.

FIG. 2C is a schematic sectional view of the mask according to an embodiment of the disclosure.

FIG. 3 is a schematic sectional view of the mask taken along line II-II′ of FIG. 1.

FIG. 4A is an enlarged schematic view of region AA illustrated in FIG. 1 according to an embodiment of the disclosure.

FIG. 4B is an enlarged schematic view of a portion of the mask according to an embodiment of the disclosure.

FIG. 5A is an enlarged schematic view of a portion of the mask according to an embodiment of the disclosure.

FIG. 5B is an enlarged schematic view of a portion of the mask according to an embodiment of the disclosure.

FIG. 6A is an enlarged schematic view of a portion of the mask according to an embodiment of the disclosure.

FIG. 6B is an enlarged schematic view of a portion of the mask according to an embodiment of the disclosure.

FIG. 7A is an enlarged schematic perspective view illustrating a protrusion in region BB of FIG. 6B.

FIG. 7B is an enlarged schematic perspective view illustrating the protrusion in region CC of FIG. 6B.

FIG. 8A is a schematic perspective view of an electronic device according to an embodiment of the disclosure.

FIG. 8B is an exploded schematic perspective view of the electronic device according to an embodiment of the disclosure.

FIG. 9A is a schematic plan view illustrating a display panel according to an embodiment of the disclosure.

FIG. 9B is a schematic sectional view of the display panel taken along line III-III′ of FIG. 9A.

FIG. 10 is a schematic plan view of the display panel according to an embodiment of the disclosure.

FIGS. 11A to 11E are schematic process views illustrating a manufacturing process of the display panel according to an embodiment of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In this specification, when it is mentioned that a component (or, a region, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components may be exaggerated for effective description. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

Terms such as first, second, and the like may be used to describe various components, but the components should not be limited by the terms. The terms may be used only for distinguishing one component from other components. For example, without departing from the spirit and scope of the disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

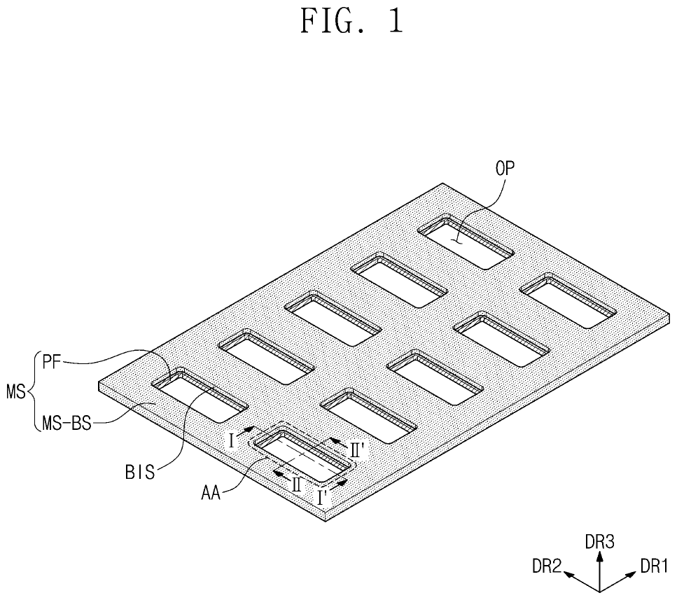

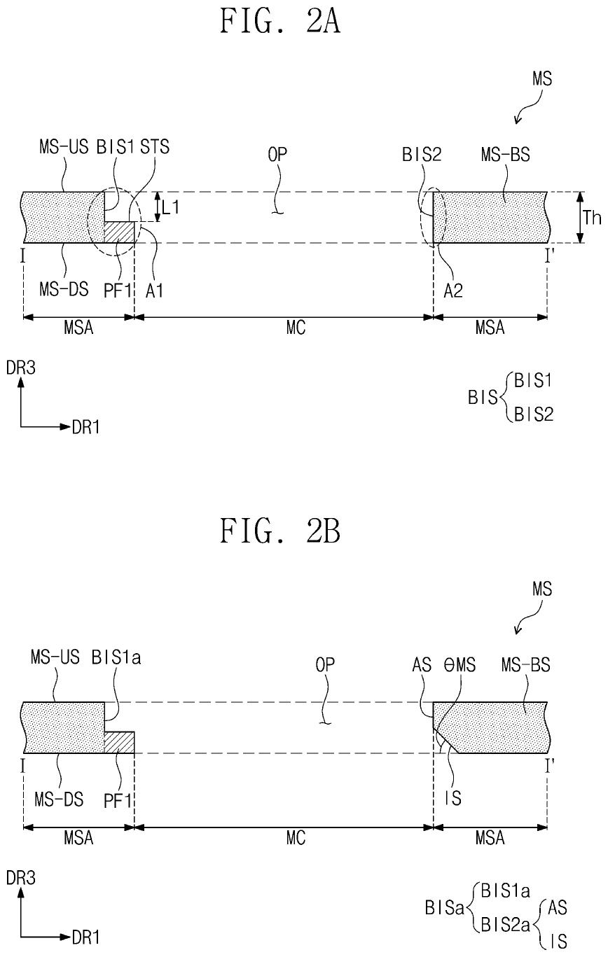

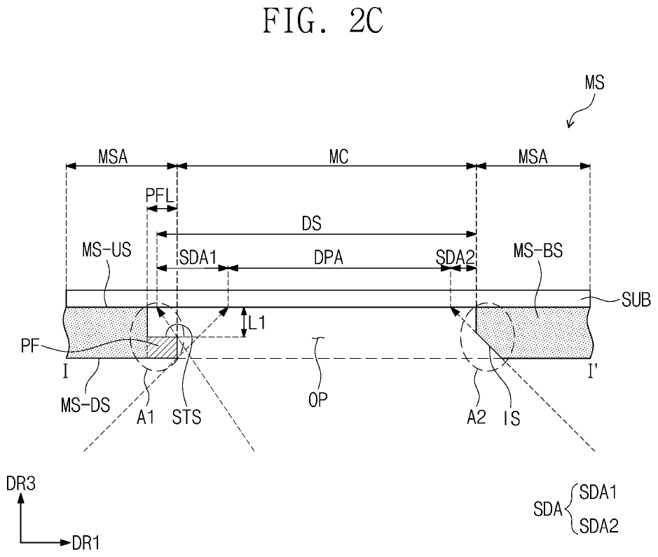

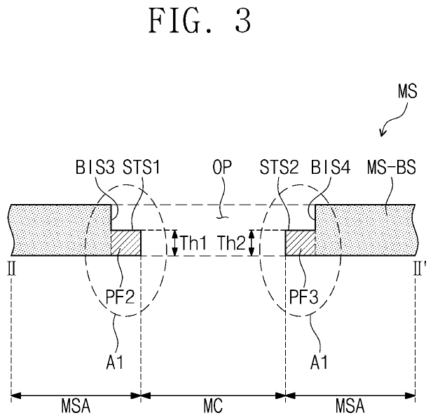

FIG. 1 is a schematic perspective view illustrating a mask according to an embodiment of the disclosure. FIG. 2A is a schematic sectional view of the mask taken along line I-I′ of FIG. 1. FIG. 2B is a schematic sectional view of the mask according to an embodiment of the disclosure. FIG. 2C is a schematic sectional view of the mask according to an embodiment of the disclosure. FIG. 3 is a schematic sectional view of the mask taken along line II-II′ of FIG. 1.

Referring to FIGS. 1 and 2A, the mask MS may include a base sheet MS-BS having an opening OP defined therein and a protrusion PF. The base sheet MS-BS may include an upper surface MS-US (hereinafter, referred to as the first surface) on which a target substrate SUB (refer to FIG. 2C) is seated, a lower surface MS-DS (hereinafter, referred to as the second surface) that faces the first surface MS-US, and an inside surface portion BIS that defines the opening OP.

The mask MS may include the protrusion PF protruding from the inside surface portion BIS of the base sheet MS-BS toward the opening OP. The protrusion PF may be formed on a partial region of the inside surface portion BIS without being formed on the entire region of the inside surface BIS.

According to an embodiment of the disclosure, the base sheet MS-BS may include multiple openings OP spaced apart from each other in plan view. The openings OP may be arranged in plan view. FIG. 1 illustrates the mask MS in which five openings OP arranged in the first direction DR1 and two openings OP arranged in the second direction DR2 are defined. However, this is illustrative, and the number of openings OP is not limited thereto. The openings OP may be arranged to have a predetermined or selected gap in one of the first direction DR1 and the second direction DR2. A deposition material may be deposited on the target substrate SUB (refer to FIG. 2C) through the openings OP.

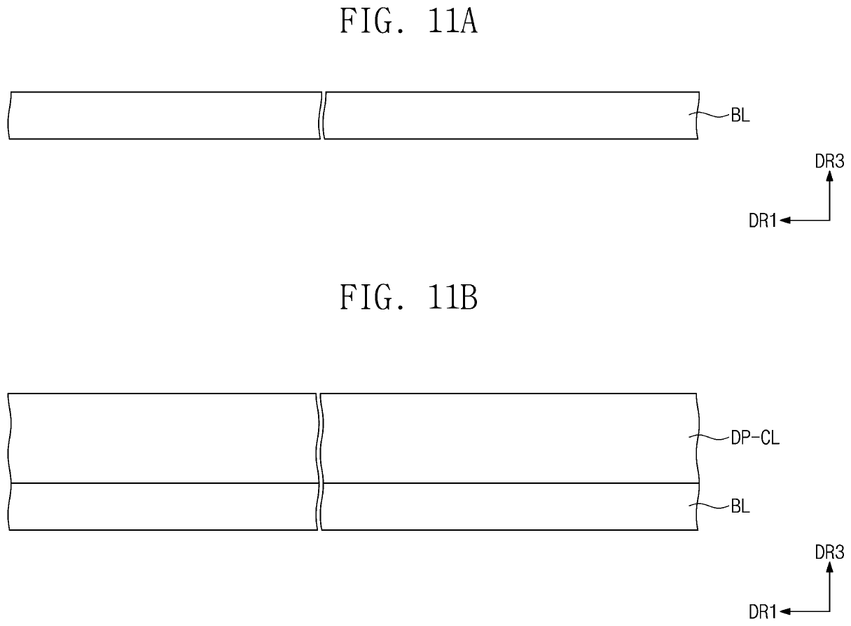

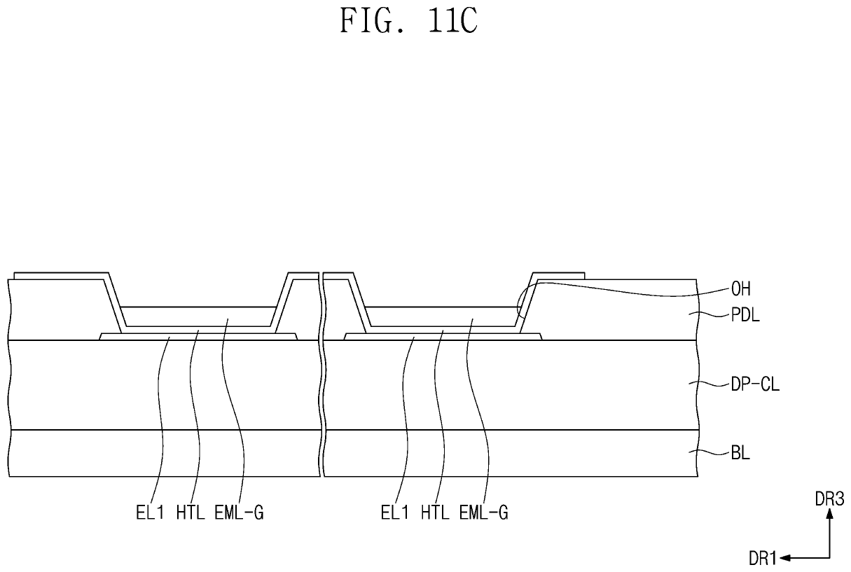

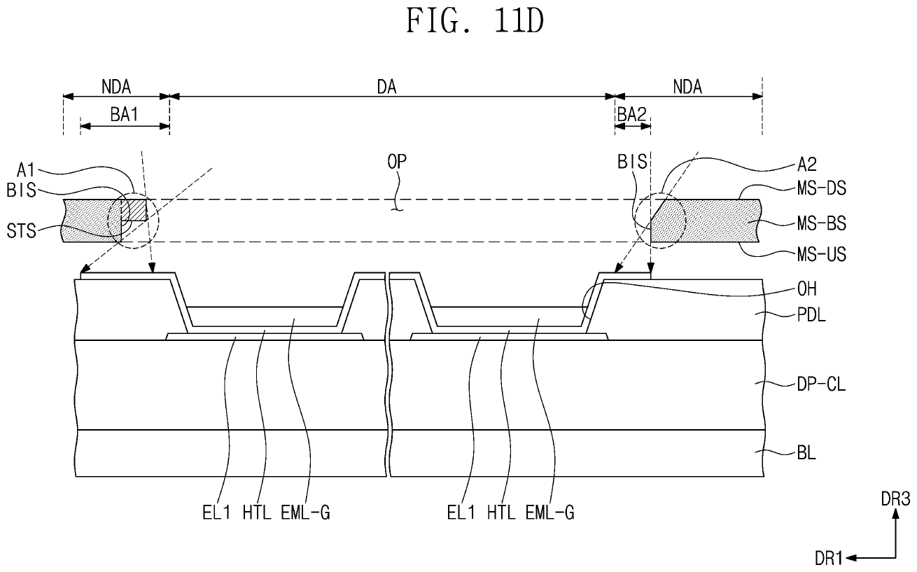

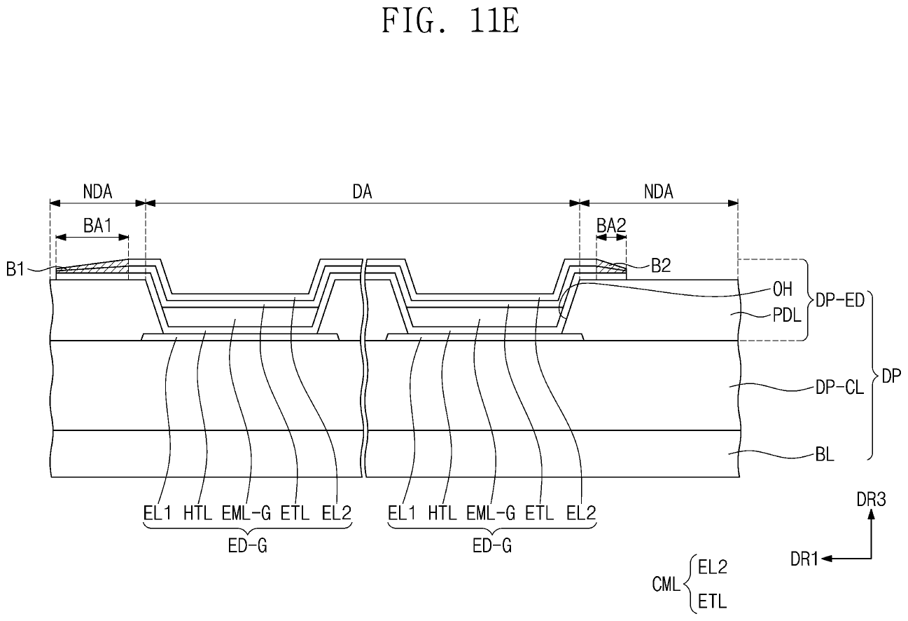

The mask MS may further include a mask frame. The mask MS of an embodiment may be used to form the common layer CML (refer to FIG. 11E) including the same material on a deposition surface of the target substrate SUB (refer to FIG. 2C). Multiple display cells may be defined on the target substrate SUB (refer to FIG. 2C) to correspond to the multiple openings OP. The mask MS according to an embodiment may correspond to an open mask for a thin-film process that is used to form the common layer CML provided as a thin film. The open mask for the thin-film process may be a mask used to form a thin-film layer of the same material on the display cells of the target substrate SUB (refer to FIG. 2C).

The mask MS may be formed of a metallic material including at least one of iron (Fe) and nickel (Ni). For example, the mask MS may include an alloy of iron and nickel. The mask MS may be manufactured to include stainless steel (SUS) or Invar. The mask MS may be formed of the same material as that of the mask frame that supports the mask MS. However, embodiments of the disclosure are not limited thereto.

The mask MS may have a thermal expansion coefficient of 5 ppm/° C. or less. The mask frame may have a thermal expansion coefficient similar to that of the mask MS. Accordingly, thermal deformation of the mask MS in a deposition process may be minimized, and thus the quality of deposition for the target substrate SUB may be improved.

The mask MS according to an embodiment may have a plate shape extending in the first direction DR1 and the second direction DR2. In an embodiment, the mask MS may have a quadrangular shape in plan view. However, embodiments are not limited thereto, and the mask MS may be provided in a different shape depending on the shape of the target substrate SUB (refer to FIG. 2C) or the shape of the mask frame that supports the mask MS.

The opening OP may have a quadrangular shape with rounded corners in plan view. However, embodiments are not limited thereto, and the shape of the opening OP in plan view may be defined as an open region MC and may be modified to have various shapes depending on the shape of the common layer CML deposited on the target substrate SUB (refer to FIG. 2C).

Referring to FIG. 2A, the protrusion PF (refer to FIG. 1) may include a first protrusion PF1 protruding from the first inside surface BIS1 of the inside surface portion BIS toward the opening OP. In the mask MS, a region in which the protrusion PF may be formed is defined as a first region A1, and a region in which the protrusion PF may not be formed is defined as a second region A2. The protrusion PF may extend from a selected inside surface of the inside surface portion BIS toward the opening OP, in a first region A1. The protrusion PF may be not provided in extending from a non-selected inside surface of the inside surface portion BIS in a second region A2. In the first region A1, the first protrusion PF1 may protrude from the first inside surface BIS1. The first protrusion PF1 may be connected with the second surface MS-DS, but may not be connected with the first surface MS-US. The inside surface portion BIS may include the first inside surface BIS1 and a second inside surface BIS2. The first inside surface BIS1 may be located in the first region A1. The second inside surface BIS2 may be located in the second region A2. The opening OP may be defined by the inside surface portion BIS.

The mask MS may include the open region MC and a masking region MSA. The open region MC may be defined inward of the masking region MSA. The open region MC may be a region corresponding to a display cell. In the mask MS of an embodiment, the open region MC may correspond to a deposition region of the target substrate SUB (refer to FIG. 2C) to which the deposition material is provided. The deposition material may be provided to the target substrate SUB depending on the shape of the open region MC. The open region MC may be defined by the second surface MS-DS of the base sheet MS-BS and may have the same shape as the shape of the opening OP viewed in a third direction DR3.

The first protrusion PF1 may include a stepped surface STS parallel to the first surface MS-US and the second surface MS-DS. The stepped surface STS may be disposed closer to the second surface MS-DS than to the first surface MS-US. Accordingly, in case that the target substrate SUB is seated on the first surface MS-US, the stepped surface STS may be spaced apart from the target substrate SUB, and the gap between the stepped surface STS and the target substrate SUB may be defined as a first gap L1. In case that the target substrate SUB is disposed to be spaced apart from the first surface MS-US by a predetermined or selected gap, the gap between the target substrate SUB and the stepped surface STS may be greater than the gap between the target substrate SUB and the first surface MS-US. For example, the gap between the target substrate SUB and the stepped surface STS may be greater than the gap between the target substrate SUB and the first surface MS-US by the first gap L1.

Since the target substrate SUB is brought into contact with the base sheet MS-BS in case seated on the mask MS, a circuit or wiring included in the contact portion may have a dent defect. However, the mask MS according to an embodiment of the disclosure may include the protrusion PF (refer to FIG. 1) having the stepped surface STS located in a lower position than the first surface MS-US, and thus the substrate SUB and the mask MS may be spaced apart from each other by the area corresponding to the stepped surface STS without making contact with each other. Accordingly, a dent defect in a circuit or wiring in a portion of the target substrate SUB that faces the stepped surface STS may be prevented.

In an embodiment, the base sheet MS-BS may have a thickness Th of 20 μm to 200 μm. The thickness Th of the base sheet MS-BS may be defined as the gap between the first surface MS-US and the second surface MS-DS. The protrusion PF according to an embodiment of the disclosure has a smaller thickness than the base sheet MS-BS. As the width of the stepped surface STS of the protrusion PF is increased, a portion of the target substrate SUB (refer to FIG. 2C) that is not in contact with the base sheet MS-BS may be increased, and thus a wide portion of the target substrate SUB (refer to FIG. 2C) where a dent defect is prevented may be secured.

Referring to FIG. 2B, an inside surface portion BISa may include a first inside surface BIS1a located in the first region A1 and a second inside surface BIS2a located in the second region A2. The second inside surface BIS2a may include a vertical surface AS and an inclined surface IS. The vertical surface AS may extend from the first surface MS-US and may be perpendicular to the first surface MS-US. The inclined surface IS may connect the vertical surface AS and the second surface MS-DS and may be inclined in a direction away from the opening OP. Since an open region MC is formed through the base sheet MS-BS in plan view, the open region MC of FIG. 2B may be the same as the open region MC of FIG. 2A even though the second inside surface BIS2a further includes the inclined surface IS in case compared to the second inside surface BIS2 of FIG. 2A.

The angle θ (that is, the tilt angle) between a virtual surface extending from the second surface MS-DS in the direction opposite to the first direction DR and the inclined surface IS may range from about 30 degrees to about 70 degrees. For example, the tilt angle θ may range from about 40 degrees to about 60 degrees. In an embodiment, in case that the tilt angle θ ranges from about 30 degrees to about 70 degrees, the ratio of the area of the deposition region to the area of the mask MS may be increased, and formation of a shadow region in the deposition region may be minimized. However, without being limited thereto, the tilt angle θ of the inclined surface IS may be diversely set to 90 degrees or less.

Referring to FIGS. 2B and 2C, the deposition material released from a deposition source may pass through the open region MC of the mask MS at a predetermined or selected angle and is deposited on the target substrate SUB. The deposition material deposited on the target substrate SUB may form a common layer CML (refer to FIG. 11E) of an organic light-emitting diode (OLED).

A deposition surface DS may correspond to a surface of the target substrate SUB on which the deposition material is deposited. The deposition surface DS may overlap the open region MC. The deposition surface DS may include a shadow region SDA on which the deposition material is not sufficiently deposited to a degree that the common layer CML can be formed and a deposition region DPA on which the deposition material is sufficiently deposited to the degree that the common layer CML can be formed. In a deposition process, the deposition material may be blocked by the protrusion PF and the inclined surface IS of the mask MS. Due to this, on the target substrate SUB overlapping the open region MC, the shadow region SDA on which the deposition material is not sufficiently deposited may be formed adjacent to the first and second regions A1 and A2 of the mask MS. Due to the shadow region SDA, the area (or, width) of the deposition region DPA may be generally smaller than the area (or, width) of the open region MC. The shadow region SDA may form a dead space in which the common layer CML is not normally deposited so that a light emitting element is not formed. The shadow region SDA may cause reduction of an effective region in which the common layer CML is normally formed, and as the effective region is reduced, an ineffective region may be expanded to increase the dead space.

The shadow region SDA may include a first shadow region SDA1 and a second shadow region SDA2. The first shadow region SDA1 may be formed to correspond to the first region A1. The protrusion PF may have a thickness smaller than the thickness Th of the base sheet MS-BS. The first shadow region SDA1 may be determined depending on the protruding length PFL of the protrusion PF and the gap L1 between the stepped surface STS and the first surface MS-US (or, the gap between the stepped surface STS and the target substrate SUB). Since the shadow region SDA is generated depending on the angle at which the deposition material is incident on the deposition surface of the target substrate SUB, the first shadow region SDA1 may be widened as the protruding length PFL of the protrusion PF and the gap L1 between the stepped surface STS and the first surface MS-US are increased. In case that the inside surface portion BISa of the base sheet MS-BS include the protrusion PF, the area of the shadow region SDA may be increased. Accordingly, The dead space on the target substrate SUB may be increased.

The second shadow region SDA2 may be formed to correspond to the second region A2. The protrusion PF may not be formed in the second region A2. In case that the inclined surface IS does not exist, the deposition material may be blocked by a corner portion of the second surface MS-DS of the mask MS. According to an embodiment of the disclosure, the inclined surface IS inclined in the direction away from the opening OP with respect to the vertical surface AS may be located in the second region A2, and the blocked deposition material may be decreased by the inclined surface IS. Specifically, the area of the second shadow region SDA2 may be smaller in case that the inclined surface IS is formed compared with a case where the inclined surface IS is not formed (that is, corresponding to FIG. 2A).

Referring to FIGS. 1 and 3, the inside surface portion BIS may include a third inside surface BIS3 and a fourth inside surface BIS4 facing each other. The protrusion PF may include a second protrusion PF2 protruding from the third inside surface BIS3 toward the opening OP and a third protrusion PF3 protruding from the fourth inside surface BIS4 toward the opening OP. According to an embodiment of the disclosure, the second protrusion PF2 and the third protrusion PF3 may have the same size and shape. However, without being limited thereto, the second protrusion PF2 and the third protrusion PF3 may have different sizes and shapes. Specifically, a first stepped surface STS1 included in the second protrusion PF2 may have a width different from that of a third stepped surface STS2 included in the third protrusion PF3. The first thickness Th1 of the second protrusion PF2 and the second thickness Th2 of the third protrusion PF3 may differ from each other.

Referring to FIGS. 1, 2A, and 3, the first protrusion PF1, the second protrusion PF2, and the third protrusion PF3 may be integrally formed without being separated from each other. However, without being limited thereto, the first protrusion PF1, the second protrusion PF2, and the third protrusion PF3 may be formed to be separated from each other and each of the first protrusion PF1, the second protrusion PF2, and the third protrusion PF3 may have different shapes and sizes.

Since the target substrate SUB is brought into contact with the base sheet MS-BS in case seated on the mask MS, a circuit or wiring disposed in the contact portion may have a dent defect. In case compared to those of FIGS. 2A and 2B, the mask MS illustrated in FIG. 3 may include the second protrusion PF2 and the third protrusion PF3 protruding from the third inside surface BIS3 and the fourth inside surface BIS4. Accordingly, the target substrate SUB and the mask MS may be spaced apart from each other by the area corresponding to the first and second stepped surfaces STS1 and STS2 without making contact with each other. Thus, dent defects in circuits and wiring in portions of the target substrate SUB that face the first and second stepped surfaces STS1 and STS2 may be prevented.

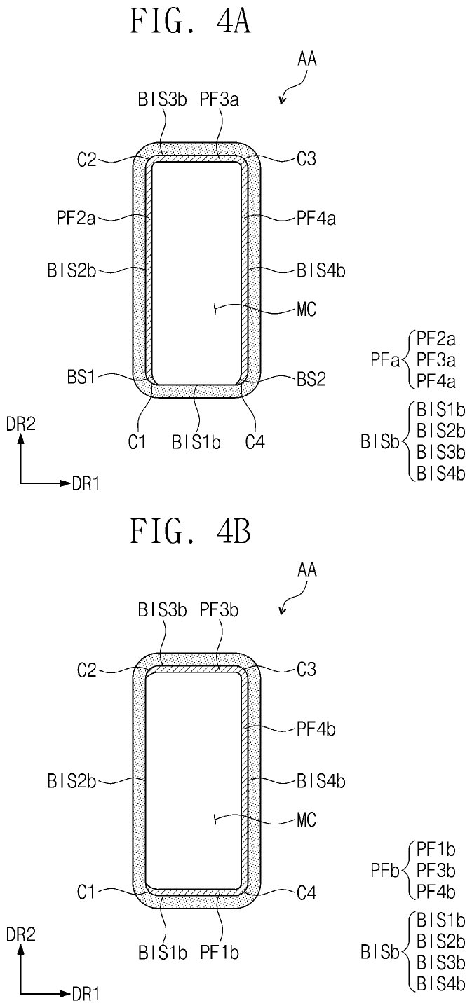

Referring to FIGS. 1, 2A, and 3, the inside surface portion BIS of the base sheet MS-BS may include four inside surfaces, for example, the first to fourth inside surfaces BIS1, BIS2, BIS3, and BIS4, and it is illustrated that the protrusion PF is not formed on one inside surface (for example, the second inside surface BIS2) among the four inside surfaces. However, without being limited thereto, the position at which the protrusion PF is provided may be diversely modified. Detailed description thereabout will be given below with reference to FIGS. 4A to 6B.

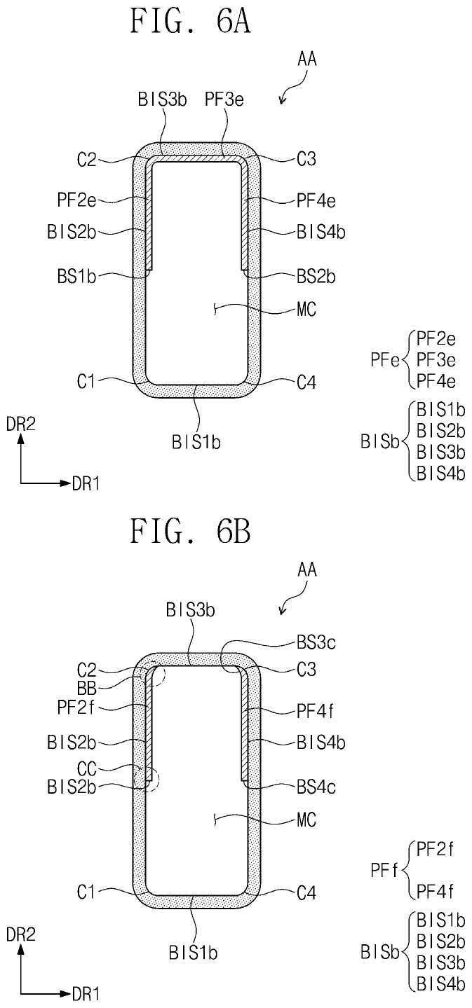

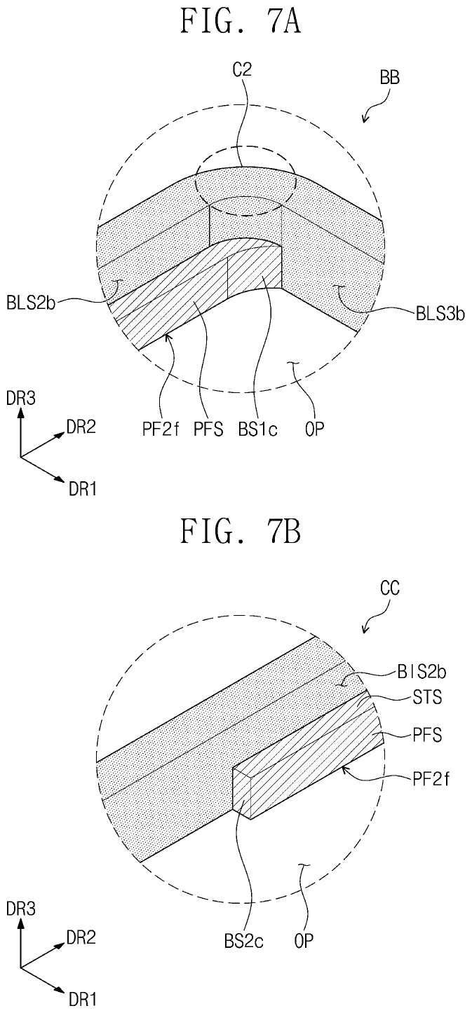

FIGS. 4A to 6B are enlarged schematic views of region AA illustrated in FIG. 1 according to embodiments of the disclosure. FIGS. 7A and 7B are enlarged schematic views illustrating a boundary surface of a protrusion on an inside surface of FIG. 6B.

Referring to FIG. 4A, an inside surface portion BISb may include first, second, third, and fourth inside surfaces BIS1b, BIS2b, BIS3b, and BIS4b. The first inside surface BIS1b may be formed parallel to the first direction DR1, and the third inside surface BIS3b may be spaced apart from the first inside surface BIS1b in the second direction DR2 crossing the first direction DR1 and may be formed parallel to the first direction DR1. The second inside surface BIS2b may be formed parallel to the second direction DR2, and the fourth inside surface BIS4b may be spaced apart from the second inside surface BIS2b in the first direction DR1 and may be formed parallel to the second direction DR2.

According to an embodiment of the disclosure, a protrusion PFa may include a second protrusion PF2a, a third protrusion PF3a, and a fourth protrusion PF4a. The second protrusion PF2a may be formed to protrude from the second inside surface BIS2b, the third protrusion PF3a may be formed to protrude from the third inside surface BIS3b, and the fourth protrusion PF4a may be formed to protrude from the fourth inside surface BIS4b. The second protrusion PF2a, the third protrusion PF3a, and the fourth protrusion PF4a may be integrally formed without being separated from each other.

The second protrusion PF2a, the third protrusion PF3a, the fourth protrusion PF4a, and the first inside surface BIS1b may define the open region MC. Since no protrusion is formed on the first inside surface BIS1b, the size of the open region MC may be larger than that in a case in which protrusions are formed to protrude from the first, second, third, and fourth inside surfaces BIS1b, BIS2b, BIS3b, and BIS4b.

Referring to FIGS. 2C and 4A, the shadow region SDA on which the deposition material is not sufficiently deposited may be formed adjacent to the first, second, third, and fourth inside surfaces BIS1b, BIS2b, BIS3b, and BIS4b. A shadow region (that is, the second shadow region SDA2) adjacent to the first inside surface BIS1b may be smaller than a shadow region (that is, the first shadow region SDA1) formed adjacent to the second protrusion PF2a, the third protrusion PF3a, and the fourth protrusion PF4a. Accordingly, a large dead space may be prevented from being formed on the target substrate SUB so as to be adjacent to the first inside surface BIS1b. For example, the protrusion PFa may not be partially formed on the inside surface portion BISb of the mask MS to correspond to a portion of the target substrate SUB where the width of a dead space is desired to be reduced, and thus the dead space formed on the target substrate SUB may be controlled in a desired shape.

The inside surface portion BISb may further include first, second, third, and fourth corner portions C1, C2, C3, and C4. The first corner portion C1 may be formed between the first inside surface BIS1b and the second inside surface BIS2b, the second corner portion C2 may be formed between the second inside surface BIS2b and the third inside surface BIS3b, the third corner portion C3 may be formed between the third inside surface BIS3b and the fourth inside surface BIS4b, and the fourth corner portion C4 may be formed between the fourth inside surface BIS4b and the first inside surface BIS1b.

According to an embodiment of the disclosure, the first, second, third, and fourth corner portions C1, C2, C3, and C4 may have a predetermined or selected curvature. Since the first, second, third, and fourth corner portions C1, C2, C3, and C4 have the predetermined or selected curvature, the first, second, third, and fourth corner portions C1, C2, C3, and C4 may have a curved shape. As illustrated in FIG. 4A, the protrusion PFa may protrude from curved surfaces of the first, second, third, and fourth corner portions C1, C2, C3, and C4. However, without being limited thereto, the protrusion PFa may protrude from only one of the curved surfaces of the first, second, third, and fourth corner portions C1, C2, C3, and C4.

The protrusion PFa may include a boundary surface BS. The boundary surface BS of the protrusion PFa may include first and second boundary surfaces BS1 and BS2. The first and second boundary surfaces BS1 and BS2 may be adjacent to the second region A2 (refer to FIG. 2A) in which the protrusion PFa is not formed and may extend from the first inside surface BIS1b.

According to an embodiment of the disclosure, the first boundary surface BS1 may be located on the first corner portion C1, and the second boundary surface BS2 may be located on the fourth corner portion C4. However, without being limited thereto, at least one of the first and second boundary surfaces BS1 and BS2 may be located on at least one of the first, second, third, and fourth corner portions C1, C2, C3, and C4. In FIG. 4A, the first and second boundary surfaces BS1 and BS2 are illustrated as curved surfaces. However, the disclosure is not limited thereto, and detailed description thereabout will be given below with reference to FIGS. 7A and 7B.

Referring to FIG. 4B, a protrusion PFb may include a first protrusion PF1b, a third protrusion PF3b, and a fourth protrusion PF4b. The first protrusion PF1b may be formed to protrude from the first inside surface BIS1b, the third protrusion PF3b may be formed to protrude from the third inside surface BIS3b, and the fourth protrusion PF4b may be formed to protrude from the fourth inside surface BIS4b. The first protrusion PF1b, the third protrusion PF3b, and the fourth protrusion PF4b may be integrally formed without being separated from each other.

The first protrusion PF1b, the third protrusion PF3b, the fourth protrusion PF4b, and the second inside surface BIS2b may define the open region MC. Referring to FIGS. 2A and 4B, since no protrusion is formed on the second inside surface BIS2b, the size of the open region MC illustrated in FIG. 4B may be larger than the size of the open region MC of the mask MS in which protrusions are formed to protrude from the first, second, third, and fourth inside surfaces BIS1b, BIS2b, BIS3b, and BIS4b.

Referring to FIGS. 2C and 4B, the shadow region SDA on which the deposition material is not sufficiently deposited may be formed adjacent to the first, second, third, and fourth inside surfaces BIS1b, BIS2b, BIS3b, and BIS4b. A shadow region (that is, the second shadow region SDA2) adjacent to the second inside surface BIS2b may be smaller than a shadow region (that is, the first shadow region SDA1) formed adjacent to the first protrusion PF1b, the third protrusion PF3b, and the fourth protrusion PF4b. Accordingly, in the vicinity of the second inside surface BIS2b, the area of the deposition region DPA may be increased by the reduced shadow region. Thus, a dead space may be reduced, and the sufficient deposition region DPA may be secured in the vicinity of the second inside surface BIS2b.

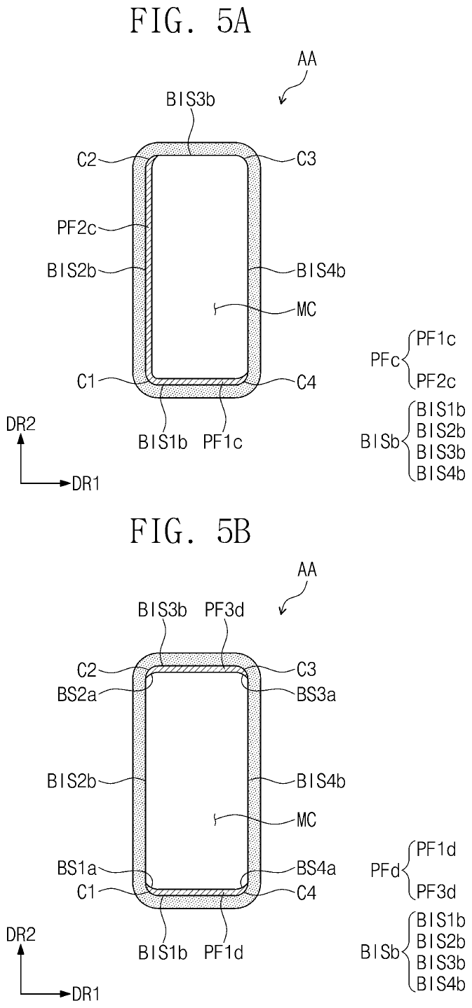

Referring to FIG. 5A, a protrusion PFc may include a first protrusion PF1c and a second protrusion PF2c. The first protrusion PF1c may be formed to protrude from the first inside surface BIS1b, and the second protrusion PF2c may be formed to protrude from the second inside surface BIS2b. The first protrusion PF1c and the second protrusion PF2c may be integrally formed without being separated from each other. However, the disclosure is not limited thereto. The protrusion PFc may be formed to protrude from the second inside surface BIS2b and the third inside surface BIS3b, may be formed to protrude from the third inside surface BIS3b and the fourth inside surface BIS4b, or may be formed to protrude from the first inside surface BIS1b and the fourth inside surface BIS4b.

According to an embodiment of the disclosure, the protrusion PFc may not be provided on the third inside surface BIS3b, the fourth inside surface BIS4b, and the third corner portion C3. Accordingly, the third inside surface BIS3b, the fourth inside surface BIS4b, and the third corner portion C3 may be included in the second region A2 (refer to FIG. 2A). However, without being limited thereto, one of the first, second, third, and fourth corner portions C1, C2, C3, and C4 may be included in the second region A2 (refer to FIG. 2A) depending on the position at which the protrusion PF2c is formed.

Since the protrusion PFc of FIG. 5A protrudes from the two inside surfaces (that is, the first and second inside surfaces BIS1b and BIS2b), the first region A1 (refer to FIG. 2A) in which the protrusion PFc is formed in the mask may be decreased, compared to those in the structures in which the protrusions PFa and PFb are formed on the three inside surfaces as illustrated in FIGS. 4A and 4B. Accordingly, a probability that a dent defect occurs in case that the target substrate SUB (refer to FIG. 2C) is seated on the mask MS may be increased. However, under the condition that a dent defect is less likely to occur, a dead space on the target substrate SUB may be more effectively reduced by decreasing the first region A1 in the mask.

Referring to FIG. 5B, a protrusion PFd may include a first protrusion PF1d and a third protrusion PF3d. The first protrusion PF1d may be formed to protrude from the first inside surface BIS1b, and the third protrusion PF3d may be formed to protrude from the third inside surface BIS3b. However, the disclosure is not limited thereto, and the protrusion PFd may be formed to protrude from the second inside surface BIS2b and the fourth inside surface BIS4b.

The first protrusion PF1d and the third protrusion PF3d may not be integrally formed and may be formed to be separated from each other. Thus, the first protrusion PF1d and the third protrusion PF3d may provide multiple first regions A1 (refer to FIG. 2A) in which the protrusion PFd is provided. The first protrusion PF1d may include first and fourth boundary surfaces BS1a and BS4a, and the third protrusion PF3d may include second and third boundary surfaces BS2a and BS3a.

According to an embodiment of the disclosure, the first boundary surface BS1a may be located on the first corner portion C1, the second boundary surface BS2a may be located on the second corner portion C2, the third boundary surface BS3a may be located on the third corner portion C3, and the fourth boundary surface BS4a may be located on the fourth corner portion C4. However, the disclosure is not limited thereto. Only the one of the first, second, third, and fourth boundary surfaces BS1a, BS2a, BS3a, and BS4a may be located on the first, second, third, and fourth corner portions C1, C2, C3, and C4, or two or more of the first, second, third, and fourth boundary surfaces BS1a, BS2a, BS3a, and BS4 may be located on the first, second, third, and fourth corner portions C1, C2, C3, and C4.

Since the protrusion PFd is not formed on two inside surfaces facing each other (that is, the second and fourth inside surfaces BIS2b and BIS4b) as illustrated in FIG. 5B, a dead space on a left, right, upper, or lower portion of the target substrate SUB may be further reduced, and thus a high degree of freedom in securing a margin may be achieved.

Referring to FIG. 6A, a protrusion PFe may include a second protrusion PF2e, a third protrusion PF3e, and a fourth protrusion PF4e. The second protrusion PF2e may protrude from the second inside surface BIS2b, the third protrusion PF3e may protrude from the third inside surface BIS3b, and the fourth protrusion PF4e may protrude from the fourth inside surface BIS4b. The third protrusion PF3e may extend to the second protrusion PF2e and the fourth protrusion PF4e, and thus the second protrusion PF2e, the third protrusion PF3e, and the fourth protrusion PF4e may be integrally formed without being separated from each other.

According to an embodiment of the disclosure, the second protrusion PF2e may protrude from a portion of the second inside surface BIS2b, and the fourth protrusion PF4e may protrude from a portion of the fourth inside surface BIS4b. The second protrusion PF2e and the fourth protrusion PF4e may extend from half of the second inside surface BIS2b and half of the fourth inside surface BIS4b, respectively, based on the second direction DR2. For example, the lengths of the second protrusion PF2e and the fourth protrusion PF4e in the second direction DR2 may be the same as each other. However, without being limited thereto, the extension lengths of the second protrusion PF2e and the fourth protrusion PF4e may differ from each other.

The protrusion PFe may include first and second boundary surfaces BS1b and BS2b. Since the second protrusion PF2e and the fourth protrusion PF4e are provided on approximately one half of the second inside surface BIS2b and approximately one half of the fourth inside surface BIS4b, respectively, the first boundary surface BS1b may be connected to the other half of the second inside surface BIS2b, and the second boundary surface BS2b may be connected to the other half of the fourth inside surface BIS4b. However, the disclosure is not limited thereto. The length of the protrusion PFe may be freely determined, and the positions of the first and second boundary surfaces BS1b and BS2b may be determined depending on the length of the protrusion PFe.

Referring to FIG. 6B, a protrusion PFf may include a second protrusion PF2f and a fourth protrusion PF4f. The second protrusion PF2f may protrude from the second inside surface BIS2b, and the fourth protrusion PF4f may protrude from the fourth inside surface BIS4b. The second protrusion PF2f may extend from the second corner portion C2 to half of the second inside surface BIS2b. The fourth protrusion PF4f may extend from the third corner portion C3 to half of the fourth inside surface BIS4b. The second protrusion PF2f and the fourth protrusion PF4f may extend in the second direction DR2 by approximately one half of the length of the second inside surface BIS2b and approximately one half of the length of the fourth inside surface BIS4b, respectively. For example, the lengths of the second protrusion PF2f and the fourth protrusion PF4f in the second direction DR2 may be the same as each other. However, without being limited thereto, the lengths of the second protrusion PF2f and the fourth protrusion PF4f in the second direction DR2 may differ from each other.

The second protrusion PF2f and the fourth protrusion PF4f may not be integrally formed and may be formed to be separated from each other. The second protrusion PF2f and the fourth protrusion PF4f may provide multiple first regions A1 (refer to FIG. 2A). Accordingly, the second protrusion PF2f may include first and second boundary surfaces BS1c and BS2c (refer to FIG. 7A), and the fourth protrusion PF4f may include third and fourth boundary surfaces BS3c and BS4c. According to an embodiment of the disclosure, the first boundary surface BS1c may be located on the second corner portion C2, the second boundary surface BS2c may be located on the second inside surface BIS2b, the third boundary surface BS3c may be located on the third corner portion C3, and the fourth boundary surface BS4c may be located on the fourth inside surface BIS4b.

Referring to FIG. 7A, the second protrusion PF2f may be formed to protrude from the second inside surface BIS2b and the second corner portion C2. The second protrusion PF2f may include a sub-inside surface PFS and the first boundary surface BS1c that are adjacent to the opening OP. The sub-inside surface PFS may be formed adjacent to the opening OP so as to face toward the opening OP and may define the opening OP. The sub-inside surface PFS may extend in the second direction DR2.

The first boundary surface BS1c may connect the sub-inside surface PFS and the third inside surface BIS3b. The first boundary surface BS1c may be inclined with respect to the first and second directions DR1 and DR2. The first boundary surface BS1c may be located on the second corner portion C2 having a predetermined or selected curvature. Since the first boundary surface BS1c is located on the second corner portion C2, the first boundary surface BS1c may be a curved surface having the predetermined or selected curvature like the second corner portion C2. However, without being limited thereto, the first boundary surface BS1c may have the shape of a flat surface having a predetermined or selected tilt angle toward the third inside surface BIS3b. In case that the second corner portion C2 does not have a curvature, the sub-inside surface PFS may extend in the second direction DR2 and may make direct contact with the third inside surface BIS3b, and thus the first boundary surface BS1c may be omitted.

The width of a dead space formed on the target substrate SUB (refer to FIG. 2C) to correspond to the second corner portion C2 may be adjusted by adjusting the shape, curvature, and tilt angle of the first boundary surface BS1c located on the second corner portion C2.

Referring to FIG. 7B, the second protrusion PF2f may protrude from the second inside surface BIS2b and may extend to a portion of the second inside surface BIS2b. The second protrusion PF2f may include the sub-inside surface PFS and the second boundary surface BS2c that are adjacent to the opening OP. The second boundary surface BS2c may connect the sub-inside surface PFS and the second inside surface BIS2b. For example, the second boundary surface BS2c may be located adjacent to the second inside surface BIS2b.

According to an embodiment of the disclosure, the second boundary surface BS2c may have the shape of a rectangular flat surface formed parallel to the first direction DR1. However, without being limited thereto, the second boundary surface BS2c may have the shape of a flat surface having a predetermined or selected tilt angle toward the second inside surface BIS2 or the shape of a curved surface having a predetermined or selected curvature.

Although not illustrated, the third boundary surface BS3c (refer to FIG. 6B) may have the same shape as the first boundary surface BS1c (refer to FIG. 6B), and the fourth boundary surface BS4c may have the same shape as the second boundary surface BS2c. However, without being limited thereto, the first, second, third, and fourth boundary surfaces BS1c, BS2c, BS3c, and BS4c may have the different shapes.

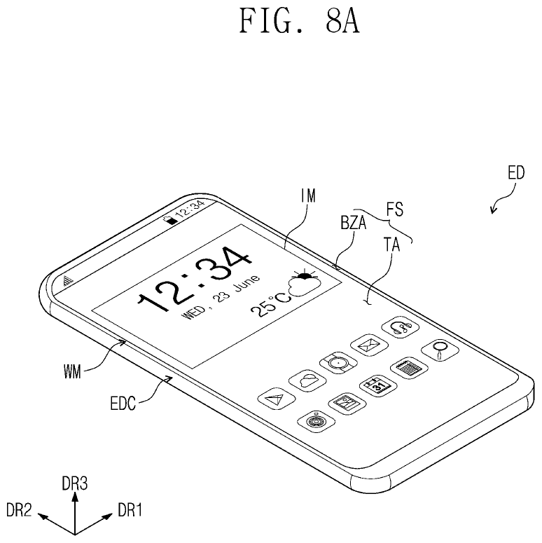

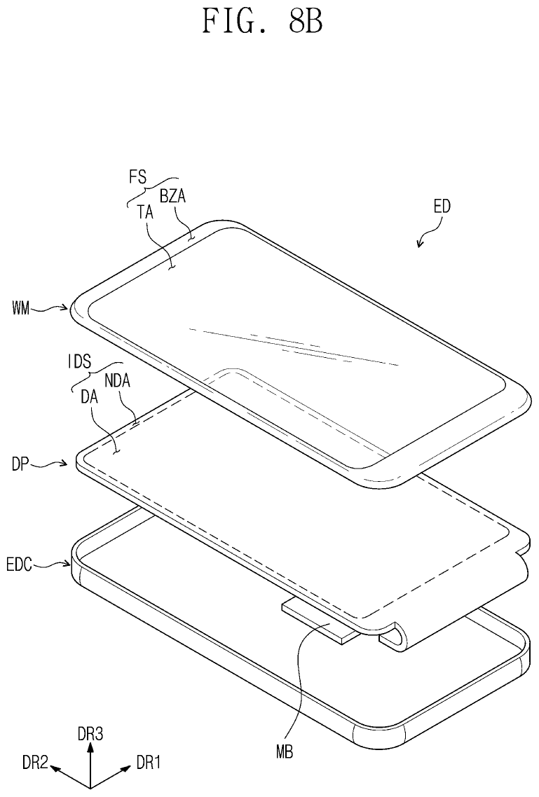

FIG. 8A is a schematic perspective view of an electronic device according to an embodiment of the disclosure. FIG. 8B is an exploded schematic perspective view of the electronic device according to an embodiment of the disclosure.

The electronic device ED may be activated in response to an electrical signal and may display an image. For example, the electronic device ED may be a large electronic device such as a television, a billboard, or the like, or may be a small and medium-sized electronic device such as a monitor, a mobile phone, a tablet computer, a car navigation unit, a game machine, or the like. The embodiments of the electronic device ED are illustrative, and the electronic device ED is not limited to any one device as long as it does not deviate from the spirit and scope of the disclosure. In this embodiment, a mobile phone is illustrated as an example of the electronic device ED.

Referring to FIG. 8, the electronic device ED may have a rectangular shape with short sides extending in the first direction DR1 and long sides extending in the second direction DR2 crossing the first direction DR1 in plan view. However, without being limited thereto, the electronic device ED may have various shapes, such as a circular shape, a polygonal shape, or the like, in plan view.

The electronic device ED of an embodiment may have flexible characteristics. The term “flexible” used herein may refer to a property of being curved and may include everything from a structure that can be fully folded to a structure that can be curved to a level of several nanometers. For example, the electronic device ED that is flexible may include a curved device or a foldable device. However, without being limited thereto, the electronic device ED may include rigid characteristics.

The electronic device ED may display an image IM in the third direction DR3 on a display surface parallel to the first direction DR1 and the second direction DR2. The image IM provided by the electronic device ED may include a still image as well as a dynamic image. In FIG. 8A, a clock window and icons are illustrated as examples of the image IM.

The display surface on which the image IM is displayed may correspond to a front surface of the electronic device ED and may correspond to a front surface FS of a window WM. A planar display surface is illustrated as an example in FIG. 8A. However, without being limited thereto, the display surface of the electronic device ED may include a curved surface bent from at least one side of a flat surface.

A front surface (or, an upper surface) and a rear surface (or, a lower surface) of each of members constituting the electronic device ED may be opposite each other in the third direction DR3, and the normal directions of the front surface and the rear surface may be substantially parallel to the third direction DR3. The separation distance between the front surface and the rear surface defined in the third direction DR3 may correspond to the thickness of the member (or, unit).

Referring to FIGS. 8A and 8b, the electronic device ED may include the window WM, a display panel DP, and a case EDC. The window WM may be coupled with the case EDC to form the exterior of the electronic device ED and may provide an inner space in which components of the electronic device ED are accommodated.

The window WM may be disposed on the display panel DP. The window WM may have a shape corresponding to the shape of the display panel DP. The window WM may cover the entire outside of the display panel DP and may protect the display panel DP from an external impact and a scratch.

The window WM may include an optically clear insulating material. For example, the window WM may include a glass substrate or a polymer substrate. The window WM may have a single-layer structure or a multi-layer structure. The window WM may further include functional layers, such as an anti-fingerprint layer, a phase control layer, and a hard coating layer, which are disposed on a transparent substrate.

The front surface FS of the window WM may include a transmissive region TA and a bezel region BZA. The transmissive region TA of the window WM may be an optically transparent region. The window WM may transmit, through the transmissive region TA, the image IM provided by the display panel DP, and a user may visually recognize the corresponding image IM.

The bezel region BZA of the window WM may be provided as a region on which a material including a predetermined or selected color is printed. The bezel region BZA of the window WM may prevent a component of the display panel DP disposed to overlap the bezel region BZA from being visible from the outside.

The bezel region BZA may be adjacent to the transmissive region TA. The shape of the transmissive region TA may be substantially defined by the bezel region BZA. For example, the bezel region BZA may be disposed around the transmissive region TA and may surround the transmissive region TA. However, this is illustrative, and the bezel region BZA may be disposed adjacent to only one side of the transmissive region TA, or may be omitted. In other embodiments, the bezel region BZA may be disposed on an inside surface rather than the front surface of the electronic device ED.

The display panel DP may be disposed between the window WM and the case EDC. The display panel DP may display the image IM in response to an electrical signal. The display panel DP according to an embodiment may be an emissive display panel, but is not particularly limited thereto. For example, the display panel DP may be an organic light emitting display panel, an inorganic light emitting display panel, or a quantum-dot light emitting display panel. An emissive layer of the organic light emitting display panel may include an organic light emitting material, and an emissive layer of the inorganic light emitting display panel may include an inorganic light emitting material. An emissive layer of the quantum-dot light emitting display panel may include quantum dots and quantum rods. Hereinafter, an example will be described where the display panel DP is an organic light emitting display panel.

The image IM provided by the electronic device ED may be displayed on a front surface IDS of the display panel DP. The front surface IDS of the display panel DP may include a display region DA and a non-display region NDA. The display region DA may be a region that is activated in response to an electrical signal and that displays the image IM. According to an embodiment, the display region DA of the display panel DP may correspond to the transmissive region TA of the window WM.

The expression “a region/portion corresponds to a region/portion” used herein means that “the regions/portions overlap each other”, but is not limited to having the same area and/or the same shape.

The non-display region NDA may be adjacent to the outside of the display region DA. For example, the non-display region NDA may surround the display region DA. However, without being limited thereto, the non-display region NDA may be defined in various shapes.

The non-display region NDA may be a region in which a drive circuit or drive wiring for driving elements disposed in the display region DA, various types of signal lines for providing electrical signals, and pads are disposed. The non-display region NDA of the display panel DP may correspond to the bezel region BZA of the window WM. The bezel region BZA may prevent components of the display panel DP disposed in the non-display region NDA from being visible from the outside.

The electronic device ED may include a circuit board MB connected to the display panel DP. The circuit board MB may be connected to one end of the display panel DP that extends in the first direction DR1. The circuit board MB may generate an electrical signal to be provided to the display panel DP. For example, the circuit board MB may include a timing controller that generates a signal to be provided to a driver of the display panel DP in response to control signals received from the outside.

In an embodiment of the disclosure, at least a portion of the non-display region NDA of the display panel DP may be bent. A portion of the display panel DP to which the circuit board MB is connected may be bent such that the circuit board MB faces toward a rear surface of the display panel DP. The circuit board MB may be disposed and assembled to overlap the rear surface of the display panel DP in plan view. However, without being limited thereto, the display panel DP and the circuit board MB may be connected through a flexible circuit board that is connected to one end of the display panel DP and one end of the circuit board MB.

The case EDC may be disposed under the display module DM and may accommodate the display panel DP. The case EDC may include glass, plastic, or a metallic material that has a relatively high stiffness. The case EDC may protect the display panel DP by absorbing an impact applied from the outside or preventing infiltration of foreign matter/moisture into the display panel DP.

The electronic device ED according to an embodiment may further include an input detection layer that is disposed on the display panel DP and that detects an external input applied from the outside. The input detection layer may detect various forms of external inputs, such as force, pressure, temperature, light, and the like, which are provided from the outside. For example, the input detection layer may detect contact by the user's body or a pen that is provided from outside the electronic device ED, or an input (e.g., hovering) applied proximate to the electronic device ED.

The electronic device ED may further include an electronic module including various functional modules for operating the display panel DP and a power supply module for supplying power required for the electronic device ED. For example, the electronic device ED may include a camera module as an example of the electronic module.

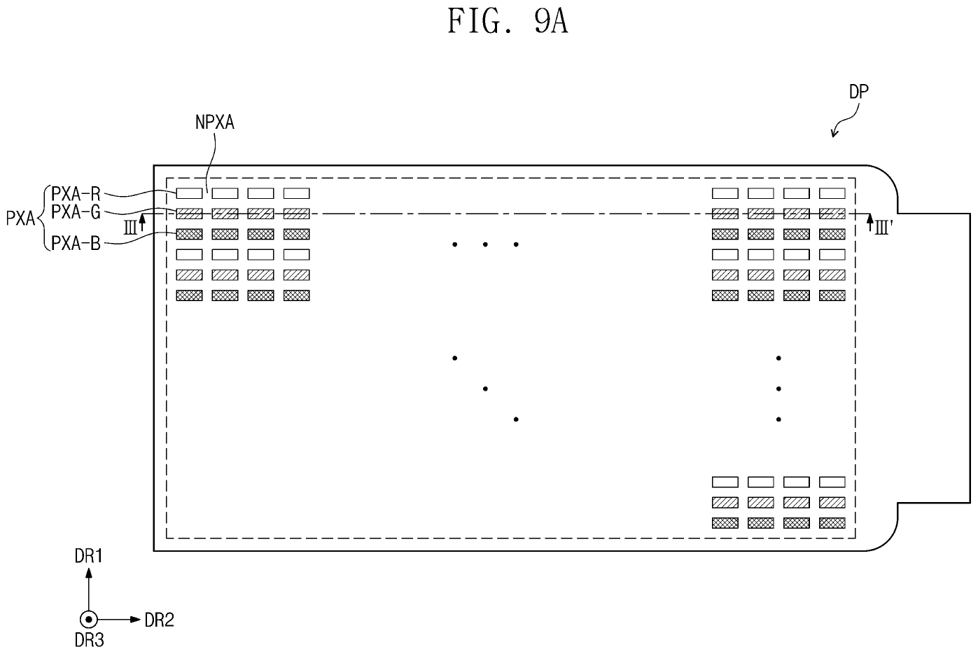

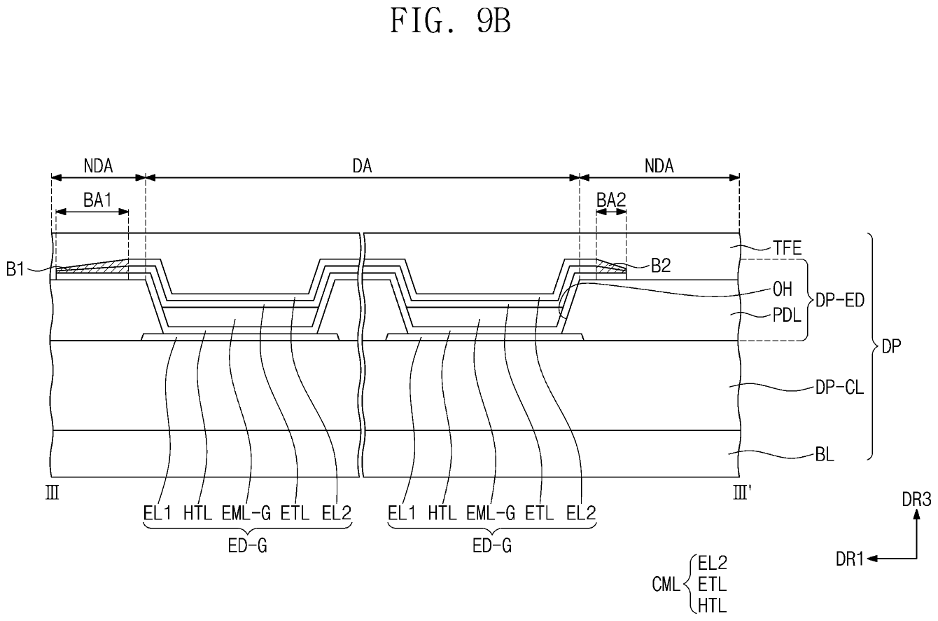

FIG. 9A is a schematic plan view illustrating the display panel according to an embodiment of the disclosure. FIG. 9B is a schematic sectional view of the display panel taken along line III-III′ of FIG. 9A. The display panel DP illustrated in FIGS. 9A and 9B may include multiple light emitting regions PXA-R, PXA-G, and PXA-B. The display panel DP may include the first light emitting regions PXA-R, the second light emitting regions PXA-G, and the third light emitting regions PXA-B separated from each other. For example, the first light emitting regions PXA-R may be red light emitting regions that emit red light, the second light emitting regions PXA-G may be green light emitting regions that emit green light, and the third light emitting regions PXA-B may be blue light emitting regions that emit blue light. The first to third light emitting regions PXA-R, PXA-G, and PXA-B may be separated from each other without overlapping each other in plan view, and a non-emissive region NPXA may be disposed between the adjacent light emitting regions PXA-R, PXA-G, and PXA-B.

An embodiment of the display panel DP illustrated in FIGS. 9A and 9B may include at least one common layer manufactured by using a mask of an embodiment to be described below. For example, among functional layers included in the display panel DP illustrated in FIGS. 9A and 9B, the common layer CML (refer to FIG. 11E) provided to overlap all of the light emitting regions PXA-R, PXA-G, and PXA-B may be provided by using the mask of an embodiment to be described below.

In the display panel DP illustrated in FIG. 9A, the light emitting regions PXA-R, PXA-G, and PXA-B may be arranged in a stripe form. For example, in the display panel DP illustrated in FIG. 9A, the multiple first light emitting regions PXA-R, the multiple second light emitting regions PXA-G, and the multiple third light emitting regions PXA-B may each be arranged in the second direction DR2. Furthermore, the multiple first light emitting regions PXA-R, the multiple second light emitting regions PXA-G, and the multiple third light emitting regions PXA-B may be alternately arranged in sequence in the first direction DR1.

A form in which the light emitting regions PXA-R, PXA-G, and PXA-B are arranged is not limited to that illustrated in FIG. 9A, and a sequence in which the first light emitting regions PXA-R, the second light emitting regions PXA-G, and the third light emitting regions PXA-B are arranged may be diversely provided in combination depending on characteristics of display quality required for the display panel DP. For example, the light emitting regions PXA-R, PXA-G, and PXA-B may be arranged in a PENTILE® form or a diamond form. Furthermore, the form in which the light emitting regions PXA-R, PXA-G, and PXA-B are arranged may be diversely adjusted or modified depending on the areas and planar shapes of the light emitting regions PXA-R, PXA-G, and PXA-B and characteristics of display quality required for the display panel DP.

The common layer commonly provided to overlap the light emitting regions PXA-R, PXA-G, and PXA-B arranged in various forms and the non-emissive region NPXA disposed between the light emitting regions PXA-R, PXA-G, and PXA-B may be manufactured by using the mask of an embodiment to be described below.

Referring to FIG. 9B, the display panel DP may include a base layer BL, a circuit layer DP-CL provided on the base layer BL, a display element layer DP-ED, and an encapsulation layer TFE disposed on the display element layer DP-ED. The display element layer DP-ED may include first, second, and third light emitting elements although not illustrated. However, the second light emitting elements ED-G (hereinafter, referred to as the light emitting elements) are representatively illustrated in FIG. 9B. FIG. 9B illustrates only two second light emitting elements ED-G located at opposite ends in the second direction DR2 among the multiple second light emitting elements ED-G that are repeatedly arranged.

The display panel DP according to an embodiment of the disclosure may be an organic electro-luminescent display panel including an organic electro-luminescent element in the display element layer DP-ED. For example, the mask according to an embodiment to be described below may be used to form a portion of the common layer CML of the display element layer DP-ED of the organic electro-luminescent display panel DP.

In an embodiment, the circuit layer DP-CL may be disposed on the base layer BL. The circuit layer DP-CL may include multiple transistors (not illustrated). Each of the transistors (not illustrated) may include a control electrode, an input electrode, and an output electrode. The circuit layer DP-CL may include multiple insulating layers.

The encapsulation layer TFE may cover the light emitting elements ED-G. The encapsulation layer TFE may seal the display element layer DP-ED. The encapsulation layer TFE may be a thin-film encapsulation layer.

Each of the light emitting elements ED-G may include a first electrode EL1, a hole transporting layer HTL, an emissive layer EML-G, an electron transporting layer ETL, and a second electrode EL2. In FIG. 9B, the emissive layers EML-G of the light emitting elements ED-G may be disposed in opening regions OH defined in a pixel defining layer PDL, and the hole transporting layer HTL, the electron transporting layer ETL, and the second electrode EL2 may be provided as the common layer CML throughout the light emitting elements ED-G. At least one of the hole transporting layer HTL, the electron transporting layer ETL, and the second electrode EL2 provided as the common layer CML in the light emitting elements ED-G of the display panel DP may be provided by using the mask MS (refer to FIG. 11D) of an embodiment to be described below.

Insulating layers included in the circuit layer DP-CL or a portion of the encapsulation layer TFE disposed on the light emitting elements ED-G may also be provided by using the mask MS (refer to FIG. 11D) of an embodiment that is referred to as an open mask.

The display panel DP may include the display region DA and the non-display region NDA. The non-display region NDA may include a first end region BA1 in which a first end portion B1 of the common layer CML is located and a second end region BA2 in which a second end portion B2 of the common layer CML is located. The first end region BA1 may include a portion corresponding to the first region A1 (refer to FIG. 11D) of the mask MS, and the second end region BA2 may include a portion corresponding to the second region A2 (refer to FIG. 11D) of the mask MS.

The first end portion B1 and the second end portion B2 may be formed through a deposition process like the common layer CML formed in the display region DA. The first end portion B1 may correspond to the first shadow region SDA1 (refer to FIG. 2C) formed by the blocking of the deposition material by the protrusion PF (refer to FIG. 2C), and the second end portion B2 may correspond to the second shadow region SDA2 (refer to FIG. 2C) formed by the blocking of the deposition material by the inclined surface IS (refer to FIG. 2C). The first end portion B1 may have a layer structure in which the thickness is gradually decreased toward an end of the first end portion B1 as the deposition material is blocked and decreased by the protrusion PF (refer to FIG. 2C). The second end portion B2 may have a layer structure in which the thickness is gradually decreased toward an end of the second end portion B2 as the deposition material is blocked and decreased by the inclined surface IS (refer to FIG. 2C). A sectional structure (that is, a first sectional structure) of the first end portion B1 may differ from a sectional structure (that is, a second sectional structure) of the second end portion B2. Specifically, the second sectional structure may have a steeper slope than the first sectional structure and may have a smaller width in the first direction DR1 than the first sectional structure.

The first and second end regions BA1 and BA2 may form dead spaces in which the light emitting elements ED-G are not sufficiently deposited. Since the second end region BA2 is formed to be smaller than the first end region BA1, a dead space in the second end region BA2 may be decreased, and thus it is possible to prevent the width of the non-display region NDA from being unnecessarily increased to secure a process margin in the second end region BA2.

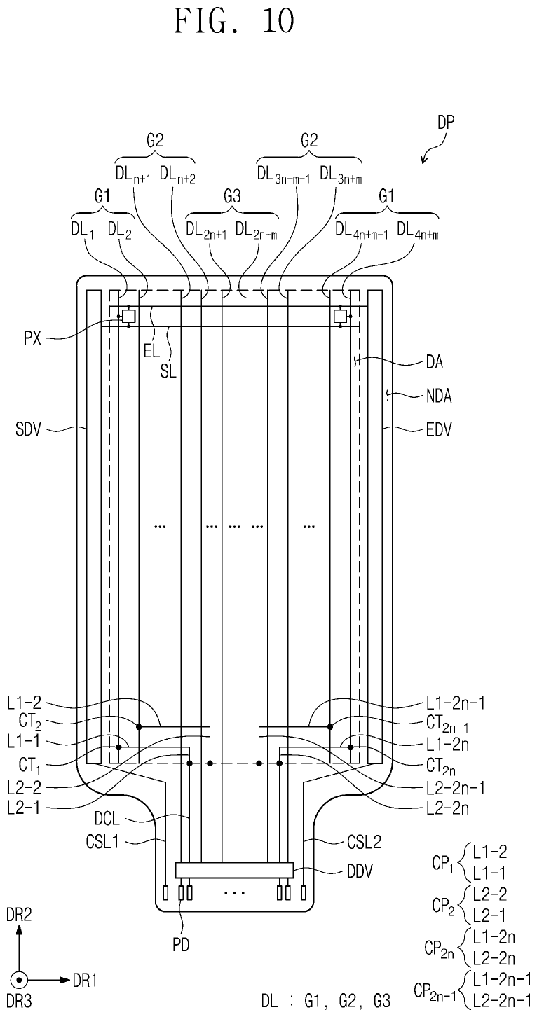

FIG. 10 is a schematic plan view of the display panel according to an embodiment of the disclosure. Referring to FIG. 10, the display panel DP may include a multiple pixels PX, multiple signal lines electrically connected to the pixels PX, a scan driver SDV, a data driver DDV, and a light emission driver EDV.

The pixels PX may be disposed in the display region DA. Each of the pixels PX may emit light in response to electrical signals applied to the pixel PX.

The scan driver SDV, the data driver DDV, and the light emission driver EDV may be disposed in the non-display region NDA of the display panel DP. The scan driver SDV and the light emission driver EDV may be disposed in the non-display regions NDA adjacent to long sides of the display panel DP, respectively.

The data driver DDV may be disposed in the non-display region NDA adjacent to a short side of the display panel DP. The data driver DDV may be provided in the form of an integrated circuit (that is, a chip) defined as a driver chip and may be mounted on the non-display region NDA of the display panel DP. However, without being limited thereto, the data driver DDV may be mounted on a separate flexible circuit board connected to the display panel DP and may be electrically connected to the display panel DP.

The signal lines may include scan lines SL, data lines DL, light emission lines EL, first and second control lines CSL1 and CSL2, connecting lines DCL, and a power line (not illustrated). Each of the pixels PX may be connected to a corresponding one of the scan lines SL and a corresponding one of the data lines DL. Without being limited thereto, the display panel DP may include more types of signal lines depending on the configuration of pixel drive circuits of the pixels PX.

FIG. 10 illustrates one scan line SL among the scan lines SL and one light emission line EL among the light emission lines EL. The scan lines SL may extend in the first direction DR1 and may be connected to the scan driver SDV. The scan lines SL may be arranged in the second direction DR2. The light emission lines EL may extend in the first direction DR1 and may be connected to the light emission driver EDV. The light emission lines EL may be arranged in the second direction DR2. Although not separately illustrated, the power line may be disposed in the non-display region NDA and may be connected to the pixels PX through a conductive line. The power line may provide a reference voltage to the pixels PL.

The data lines DL may extend in the second direction DR2 and may be arranged in the first direction DR1. The data lines DL may be divided into a first group G1, a second group G2, and a third group G3.

The display panel DP may include multiple connecting patterns CP₁, CP₂, CP₂ₙ₋₁, and CP₂ₙ disposed in the display region DA. Each of data lines DL₁, DL₂, DL₄ₙ₊ₘ₋₁, and DL₄ₙ₊ₘ of the first group G1 may be connected to a corresponding one of the multiple connecting patterns CP₁, CP₂, CP₂ₙ₋₁, and CP₂ₙ. Data lines DLₙ₊₁, DLₙ₊₂, DL₃ₙ₊ₘ₋₁, and DL₃ₙ₊ₘ of the second group G2 may overlap at least one of the connecting patterns CP₁, CP₂, CP₂ₙ₋₁, and CP₂ₙ in plan view. Data lines DL₂ₙ₊₁ and DL₂ₙ₊ₘ of the third group G3 may not overlap the connecting patterns CP₁, CP₂, CP₂ₙ₋₁, and CP₂ₙ in plan view. Here, “n” may be a natural number, and “m” may be 0 or a natural number.

The data lines DL₁, DL₂, DL₄ₙ₊ₘ₋₁, and DL₄ₙ₊ₘ of the first group G1 may be disposed adjacent to outer boundaries of the display region DA that extend in the second direction DR2. Among the data lines DL₁, DL₂, DL₄ₙ₊ₘ₋₁, and DL₄ₙ₊ₘ of the first group G1, the data lines DL₁ and DL₂ may be arranged in the first direction DR1 from the left boundary of the display region DA toward a central portion of the display region DA. For example, the data lines DL₁ and DL₂ of the first group G1 arranged on the left side may be arranged in n columns. FIG. 10 illustrates the data lines DL₁ and DL₂ of the first group G1 arranged in the first column and the second column.

The data lines DLₙ₊₁, DLₙ₊₂, DL₃ₙ₊ₘ₋₁, and DL₃ₙ₊ₘ of the second group G2 may be arranged in the first direction DR1 from the data line disposed closest to the central portion of the display region DA among the data lines DL₁, DL₂, DL₄ₙ₊ₘ₋₁, and DL₄ₙ₊ₘ of the first group G1 toward the central portion of the display region DA. The data lines DLₙ₊₁ and DLₙ₊₂ of the second group G2 disposed adjacent to the left side of the display region DA may be arranged in the first direction DR1 from the data line in the n^{th} column of the first group G1. Accordingly, the data line of the second group G2 arranged closest to the data lines DL₁ and DL₂ of the first group G1 disposed on the left side may be the data line in the (n+1)^{th} column. The data lines DLₙ₊₁ and DLₙ₊₂ of the second group G2 disposed on the left side may include data lines arranged from the (n+1)^{th} column to the 2n^{th} column, and FIG. 10 illustrates the data lines DLₙ₊₁ and DLₙ₊₂ of the second group G2 that are arranged in the (n+1)^{th} column and the (n+2)^{th} column.

The data lines DL₂₊₁ and DL₂ₙ₊ₘ of the third group G3 may be disposed in a region corresponding to the central portion of the display region DA. The data lines DL₂₊₁ and DL₂ₙ₊ₘ of the third group G3 may be disposed between the data lines DLₙ₊₁, DLₙ₊₂, DL₃ₙ₊ₘ₋₁, and DL₃ₙ₊ₘ of the second group G2 that are disposed on the left side and the right side and may be arranged in the first direction DR1. The leftmost data line DL₂₊₁ of the data lines DL₂₊₁ and DL₂ₙ₊ₘ of the third group G3 may be the data line DL₂₊₁ in the (2n+1) column that is disposed adjacent to the data line in the 2n^{th} column included in the second group G2 in the first direction DR1. The data lines DL₂ₙ₊₁ and DL₂ₙ₊ₘ of the third group G3 may be arranged in m columns.

The data lines DL₃ₙ₊ₘ₋₁ and DL₃ₙ₊ₘ of the second group G2 disposed on the right side of the display region DA may be arranged in the first direction DR1 from the rightmost data line DL₂ₙ₊ₘ of data lines DL₂ₙ₊₁ and DL₂ₙ₊ₘ of the third group G3. The data line closest to the data lines DL₂ₙ₊₁ and DL₂ₙ₊ₘ of the third group G3 of the data lines DL₃ₙ₊ₘ₋₁ and DL₃ₙ₊ₘ of the second group G2 disposed on the right side may be the data line in the (2n+m+1)^{th} column. The data lines DL₃ₙ₊ₘ₋₁ and DL₃ₙ₊ₘ of the second group G2 disposed on the right side may include the data lines arranged from the (2n+m+1)^{th} column to the (3n+m)^{th} column, and FIG. 10 illustrates the data lines DL₃ₙ₊ₘ₋₁ and DL₃ₙ₊ₘ arranged in the (3n+m−1)^{th} column and the (3n+m)^{th} column among the data lines of the second group G2 disposed on the right side.

The data lines DL₄ₙ₊ₘ₋₁ and DL₄ₙ₊ₘ of the first group G1 disposed on the right side of the display region DA may be arranged in the first direction DR1 from the data line in the rightmost (3n+m)^{th} column of the data lines DL₃ₙ₊ₘ₋₁ and DL₃ₙ₊ₘ of the second group G2 disposed on the right side of the display region DA. The data line closest to the data lines of the second group G2 of the data lines DL₄ₙ₊ₘ₋₁ and DL₄ₙ₊ₘ of the first group G1 disposed on the right side may be the data line in the (3n+m+1)^{th} column. The data lines DL₄ₙ₊ₘ₋₁ and DL₄ₙ₊ₘ of the first group G1 disposed on the right side may include the data lines arranged from the (3n+m+1)^{th} column to the (4n+m)^{th} column, and FIG. 10 illustrates the data lines DL₄ₙ₊ₘ₋₁ and DL₄ₙ₊ₘ arranged in the (4n+m−1)^{th} column and the (4n+m)^{th} column among the data lines of the first group G1 disposed on the right side.

The data lines of the first group G1 and the second group G2 disposed on the left side of the display region DA may be arranged to be symmetrical to the data lines of the first group G1 and the second group G2 disposed on the right side of the display region DA, with the data lines of the third group G3 therebetween. In an embodiment, the number of data lines DL₁, DL₂, DL₄ₙ₊ₘ₋₁, and DL₄ₙ₊ₘ of the first group G1 and the number of data lines DLₙ₊₁, DLₙ₊₂, DL₃ₙ₊ₘ₋₁, and DL₃ₙ₊ₘ of the second group G2 may be the same as each other. In this specification, the above description has been given based on the first group G1 and the second group G2 including data lines arranged in 2n columns. However, the number of data lines included in each group is not limited thereto and may be differently designed.

In an embodiment, the data lines DL₂ₙ₊₁ and DL₂ₙ₊ₘ of the third group G3 may be omitted. In the case in which the data lines DL₂ₙ₊₁ and DL₂ₙ₊ₘ of the third group G3 are omitted, “m” may correspond to 0. The data lines DL may be divided into the first group G1 and the second group G2. Accordingly, in an embodiment, the data lines of the first group G1 may be arranged in directions from the left and right boundaries of the display region DA toward the central portion of the display region DA, and the data lines of the first group G1 disposed on the left side of the display region DA and the data lines of the first group G1 disposed on the right side of the display region DA may be spaced apart from each other with the data lines of the second group G2 therebetween.

The connecting lines DCL may be disposed in the non-display region NDA and may extend in the second direction DR2. The connecting lines DCL may be disposed in a region between the data driver DDV and the display region DA. Ends of the connecting lines DCL may be connected to the data driver DDV via the non-display region NDA. Each of the connecting lines DCL may electrically connect a corresponding one of the data lines DL to the data driver DDV.

The data lines DL₁, DL₂, DL₄ₙ₊ₘ₋₁, and DL₄ₙ₊ₘ of the first group G1 may be connected to the connecting lines DCL via the connecting patterns CP₁, CP₂, CP₂ₙ₊₁, and CP₂ₙ connected to correspond to the data lines. The data lines DLₙ₊₁, DLₙ₊₂, DL₃ₙ₊ₘ₋₁, and DL₃ₙ₊ₘ of the second group G2 and the data lines DL₂ₙ₊₁ and DL₂ₙ₊ₘ of the third group G3 may each be directly connected to a corresponding one of the connecting lines DCL.

The connecting patterns CP₁, CP₂, CP₂ₙ₋₁, and CP₂ₙ may electrically connect the data lines DL₁, DL₂, DL₄ₙ₊ₘ₋₁, and DL₄ₙ₊ₘ of the first group G1 connected to correspond thereto to the connecting lines DCL and the data driver DDV. Since the connecting patterns CP₁, CP₂, CP₂ₙ₋₁, and CP₂ₙ are disposed via the display region DA, the area of a wiring arrangement region required to connect, to the data driver DDV, the data lines DL₁, DL₂, DL₄ₙ₊ₘ₋₁, and DL₄ₙ₊ₘ of the first group G1 that are disposed adjacent to the left and right boundaries of the display region DA may be decreased. For example, each of the connecting patterns CP₁, CP₂, CP₂ₙ₋₁, and CP₂n may include a first line extending in the first direction DR1 and a second line extending in the second direction DR2. The first lines L1-1 to L1-2n and the data lines DL₁ to DL₄ₙ₊ₘ may be connected on the display region DA. The points at which the first lines L1-1 to L1-2n and the data lines DL₁ to DL₄ₙ₊ₘ are connected may be defined as contact portions CT₁ to CT₂ₙ, and the contact portions CT₁ to CT₂ₙ may be disposed on the display region DA. Since the contact portions CT₁ to CT₂ₙ are disposed on the display region DA, the area of the lower non-display region NDA corresponding to the region between the display region DA and the data driver DDV may be decreased, and thus the area of a dead space of the display panel DP may be decreased.

Pads PD may be disposed adjacent to a lower end of the non-display region NDA and may be arranged in the first direction DR1. The pads PD may be disposed closer to the lower end of the display panel DP than the data driver DDV. The pads PD may be portions connected to the circuit board MB (refer to FIG. 8B). The pads PD may be electrically connected to the data lines DL, the first control line CSL1, and the second control line CSL2, respectively. Although not separately illustrated, the power line of the display panel DP may be electrically connected to a corresponding one of the pads PD.

The first control line CSL1 may be connected to the scan driver SDV. The second control line CSL2 may be connected to the light emission driver EDV.

The scan driver SDV may generate multiple scan signals in response to a scan control signal. The scan signals may be applied to the pixels PX through the scan lines SL. The data driver DDV may generate multiple data voltages corresponding to image signals in response to a data control signal. The data voltages may be applied to the pixels PX through the data lines DL. The light emission driver EDV may generate multiple light emission signals in response to a light emission control signal. The light emission signals may be applied to the pixels PX through the light emission lines EL.

The pixels PX may receive the data voltages in response to the scan signals. The pixels PX may display an image by emitting light having luminance corresponding to the data voltages in response to the light emission signals. Light emission time of the pixels PX may be controlled by the light emission signals. Accordingly, the display panel DP may output the image through the display region DA by the pixels PX.

FIGS. 11A to 11E are schematic process views illustrating a manufacturing process of the display panel according to an embodiment of the disclosure.

Referring to FIGS. 11A and 11B, the circuit layer DP-CL may be formed on the base layer BL. The circuit layer DP-CL may include pixel drive circuits and a sensor driver circuit that are not illustrated. The display element layer DP-ED (refer to FIG. 9B) may be formed on the circuit layer DP-CL.

FIG. 11C illustrates a step of forming the first electrodes EL1, the pixel defining layer PDL, the hole transporting layer HTL, and the emissive layers EML-G included in the display element layer DP-ED (refer to FIG. 9B). The first electrodes EL1 are formed on the circuit layer CP-CL, and the pixel defining layer PDL is formed. Although the step of forming the pixel defining layer PDL is not illustrated, a step of forming a preliminary insulating layer and performing a photolithography process such that the preliminary insulating layer is subjected to patterning may be included. The preliminary insulating layer may include an organic insulating material. Thereafter, the hole transporting layer HTL and the emissive layers EML-G may be formed. The hole transporting layer HTL may be commonly disposed in the emissive region PXA (refer to FIG. 9A) and the non-emissive region NPXA (refer to FIG. 9A). The emissive layers EML-G may be provided in a pattern form to correspond to the opening regions OH. Compared to the hole transporting layer HTL having a film form, the emissive layers EML-G may be deposited in a different way. The hole transporting layer HTL may be commonly formed for the pixels PX (refer to FIG. 10) by using an open mask (that is, the mask illustrated in FIG. 1). The emissive layers EML-G may be formed in a pattern form to correspond to the opening regions OH by using a pixel unit mask.

Referring to FIGS. 11D and 11E, the common layer CML may be formed on the emissive layers EML-G and the hole transporting layer HTL. The common layer CML may include the electron transporting layer ETL and the second electrode EL2. However, without being limited thereto, the common layer CML may include the hole transporting layer HTL. Although not illustrated, the common layer CML may be formed through a deposition process by using the mask MS according to an embodiment of the disclosure.

The mask MS according to an embodiment of the disclosure may include the base sheet MS-BS having the opening OP defined therein and the protrusion PF. The base sheet MS-BS may include the first surface MS-US on which the target substrate SUB is seated, the second surface MS-DS facing the first surface MS-US, and the inside surface portion BIS formed to face toward the opening OP, and the opening OP may be defined by the inside surface BIS. The protrusion PF may be formed on a partial region of the inside surface portion BIS of the base sheet MS-BS without being formed on the entire region of the inside surface BIS. The region in which the protrusion PF is formed may be defined as the first region A1, and the region in which the protrusion PF is not formed may be defined as the second region A2.

The common layer CML may be formed through a deposition process of the mask MS. The common layer CML may be formed to correspond to the open region MC of the mask MS. More specifically, in addition to the region corresponding to the open region MC of the mask MS, the shadow region SDA (refer to FIG. 2C) on which the deposition material is not sufficiently deposited may be formed. In a case in which the shadow region SDA of a deposition pattern is formed to be wide, the shadow region SDA may be formed outside the deposition region (e.g., on a pad portion included in the display panel such as a dead space), and therefore the display panel may have a defect.

The common layer CML may include the first end portion B1 and the second end portion B2. The first end portion B1 may be formed by the first region A1 in which the protrusion PF is formed, and the second end portion B2 may be formed by the second region A2 in which the protrusion PF is not formed.

Since the first end portion B1 is deposited by the first region A1 in which the protrusion PF is formed, the first shadow region SDA1 (refer to FIG. 2C) may be formed to be wide. Accordingly, a wide dead space may be formed. However, a dent defect in a circuit included in the display panel DP that corresponds to the stepped surface STS may be prevented as described above.

Since the second end portion B2 is deposited by the second region A in which the protrusion PF is not formed, the second shadow region SDA2 (refer to FIG. 2C) may be formed to be narrow. Accordingly, a dead space may be decreased, compared to that in the case of the first end portion B1. Referring to FIG. 10, since the contact portions CT₁ to CT₂ₙ are disposed on the display region DA, the area of the lower non-display region NDA corresponding to the region between the display region DA and the data driver DDV may be decreased, and thus the area of a dead space of the display panel DP may be decreased. Correspondingly, the second end portion B2 may be disposed in the direction opposite to the second direction DR2 of the display region DA of the display panel DP, and thus the display panel DP having a reduced dead space may be provided.

The display panel DP may include the display region DA and the non-display region NDA. The non-display region NDA may include the first end region BA1 in which the first end portion B1 of the common layer CML is located and the second end region BA2 in which the second end portion B2 of the common layer CML is located.

According to the embodiments of the disclosure, an increase in dead space on the target substrate due to the shadow region may be prevented by removing the protrusion in a partial region to solve the problem in which the shadow region is formed on the target substrate due to the protrusion protruding toward the opening of the mask to prevent a dent defect in the target substrate.

In manufacturing the display panel using the mask, a degree of freedom in securing a margin for the shadow region may be improved.

While the disclosure has been described with reference to embodiments thereof, it will be apparent to those of ordinary skill in the art that various changes and modifications may be made thereto without departing from the spirit and scope of the disclosure.

What is claimed is:

1. A mask comprising:
a base sheet including:
a first surface on which a target substrate is seated;
a second surface that faces the first surface; and
an inside surface portion that defines an opening formed through the first surface and the second surface; and
at least one protrusion that extends from a selected inside surface of the inside surface portion toward the opening, in a first region of the base sheet, wherein
the at least one protrusion includes a stepped surface,
a gap between the stepped surface and the target substrate is greater than a gap between the first surface and the target substrate, and
the at least one protrusion is not provided extending from a non-selected inside surface of the inside surface portion in a second region of the base sheet.

2. The mask of claim 1, wherein the at least one protrusion includes first and second boundary surfaces adjacent to the second region and that extend from the inside surface.

3. The mask of claim 2, wherein the first and second boundary surfaces include different shapes.

4. The mask of claim 2, wherein
the at least one protrusion includes a plurality of protrusions, and
a plurality of boundary surfaces corresponding to the plurality of protrusions are provided.

5. The mask of claim 2, wherein
the inside surface portion includes first to fourth corner portions, and
at least one of the first and second boundary surfaces is located on at least one of the first to fourth corner portions.

6. The mask of claim 5, wherein the first to fourth corner portions include a curvature.

7. The mask of claim 6, wherein the at least one protrusion protrudes from at least one of the first to fourth corner portions.

8. The mask of claim 6, wherein at least one of the first to fourth corner portions is included in the second region.

9. The mask of claim 2, wherein
the inside surface portion includes:
a first inside surface;
a second inside surface;
a third inside surface; and
a fourth inside surface,
the first and third inside surfaces are parallel to a first direction, and
the second and fourth inside surfaces are parallel to a second direction intersecting the first direction.

10. The mask of claim 9, wherein
the first inside surface is spaced apart from the third inside surface in the second direction, and
the at least one protrusion protrudes from the first inside surface or the third inside surface.

11. The mask of claim 10, wherein the at least one protrusion is integrally formed without protruding and separating from the adjacent second or fourth inside surface.

12. The mask of claim 10, wherein the at least one protrusion is integrally formed without protruding and separating from a portion of the adjacent second inside surface and a portion of the adjacent fourth inside surface.

13. The mask of claim 9, wherein
the at least one protrusion includes a plurality of protrusions,
the second inside surface is spaced apart from the fourth inside surface in the first direction, and
the plurality of protrusions protrude from the second inside surface and the fourth inside surface, respectively.

14. The mask of claim 13, wherein the plurality of protrusions protrude from a portion of the second inside surface and a portion of the fourth inside surface corresponding to the portion of the second inside surface, respectively.

15. The mask of claim 9, wherein at least one of the first and second boundary surfaces is adjacent to at least one of the first to fourth inside surfaces.

16. The mask of claim 1, wherein the inside surface portion includes:
a vertical surface physically connected to the first surface in the second region and perpendicular to the first surface; and
an inclined surface that physically connects the vertical surface and the second surface and inclined in a direction away from the opening.

17. The mask of claim 1, wherein the opening is provided in plural, each including a same planar shape.

18. A method for manufacturing a display panel, the method comprising:
forming a circuit layer disposed on a base layer; and
forming an element layer disposed on the circuit layer and including a common layer,
wherein the forming of the element layer includes forming the common layer using a mask,
the common layer includes a first end portion including a first sectional structure and a second end portion including a second sectional structure different from the first sectional structure,
the mask includes:
a base sheet including:
a first surface on which a target substrate is seated;
a second surface that faces the first surface; and
an inside surface portion that defines an opening formed through the first surface and the second surface; and
at least one protrusion that extends from a selected inside surface of the inside surface portion toward the opening, in at least one first region of the base sheet corresponding to the first end portion of the common layer,
the at least one protrusion includes a stepped surface including a step from the first surface, and
the at least one protrusion is not provided in extending from a non-selected inside surface of the inside surface portion in a second region of the base sheet corresponding to the second end portion of the common layer.

19. The method of claim 18, wherein
the base layer includes a display region and a non-display region,
the display panel includes:
a plurality of data lines arranged in the display region in a first direction and that extend in a second direction intersecting the first direction; and
a plurality of connecting patterns that electrically connect connecting lines connected to a data driver disposed in the non-display region and the plurality of data lines, and
each of the plurality of connecting patterns includes a first line connected to one of the plurality of data lines and that extends in the first direction and a second line connected to the first line and that extends in the second direction.

20. The method of claim 19, wherein contact portions between the first lines and the data lines are disposed in the display region.
